(19) United States
(12) Patent Application Publication
(10) Pub. No.: US 2026/0186064 A1
(43) Pub. Date: Jul. 2, 2026

(54) METHOD FOR DETERMINING ALTERNATE STATE OF HEALTH PARAMETERS

(71) Applicant: Fluence Energy, LLC, Arlington, VA (US)

(72) Inventors: Brett Lance Galura, Vienna, VA (US); Thomas Jeffrey Winter, Decatur, GA (US)

(73) Assignee: Fluence Energy, LLC, Arlington, VA (US)

(21) Appl. No.: 18/867,878

(22) PCT Filed: Sep. 27, 2024
(86) PCT No.: PCT/US2024/048752

§ 371 Date: Nov. 21, 2024

Related U.S. Application Data
(60) Provisional application No. 63/541,133, filed on Sep. 28, 2023.

(51) Int. Cl. G01R 31/392; G01R 31/3832; H01M 10/42; H02J 7/50; H02J 7/82; H02J 7/84

(52) U.S. Cl. CPC G01R 31/392; G01R 31/3832; H01M 10/4285; H01M 2010/4271; H02J 7/50; H02J 7/82; H02J 7/84

(57) ABSTRACT

A system includes a plurality of energy storage nodes including a plurality of battery modules, and a control system. At least one processor of the control system is configured to: obtain an initial battery capacity and an initial state of charge for at least one battery module; control at least one sensor to measure and record electrical current flow between multiple components to provide raw data for electrical current within the system for a predetermined period of time; determine a present state of charge of the battery over an elapsed time; determine an integrated current value based on the measured raw data; determine a remaining capacity of the at least one battery module at an end of the elapsed time; and determine an estimated state of health of the at least one battery module based upon the initial battery capacity and the determined remaining capacity including the integrated current value.

### CROSS-REFERENCE TO RELATED APPLICATIONS

This application claims priority under 35 U.S.C. § 120 to U.S. Provisional Patent Application No. 63/541,133 filed on Sep. 28, 2023, titled “Method for Determining Alternate State of Health Parameters,” the entire disclosure of which is incorporated by reference herein.

### TECHNICAL FIELD

The present subject matter relates to analytics system design and embedded methods of analysis for a battery in energy storage systems, wherein the state of health of a battery system is determined based upon observable data or phenomena.

### BACKGROUND

The batteries of battery energy storage systems, compound energy storage systems, as well as of energy provisioning systems degrade with use, losing capacity, and lowering the state of health (SoH) of the batteries. SoH is a measure of how much capacity remains in the batteries as the batteries age, and is therefore a useful parameter in adjusting system operation, as well as planning for activities such as capacity augmentation of the system.

However, measuring how much capacity remains in the batteries is non-trivial. The most accurate approach is to conduct a capacity test, which charges a system up to top of charge and then discharges it down to bottom of charge. This formal capacity test protocol is time consuming, and also disrupts normal system operation and revenue generation. Therefore, the capacity test protocol is conducted only periodically (e.g., annually). Battery management systems also self-report an estimate of SoH, based on the manufacturer's stated capacity. However, it is well known in the industry that these stated capacity values, as well as the corresponding estimates of SoH, are highly inaccurate and do not reflect actual remaining capacity. In particular, manufacturers may report the state of health of a battery based on a predefined algorithm that marks the battery as more degraded as time goes on, without concern for the actual capacity of the battery as compared to the original nominal capacity of the battery.

### SUMMARY

Hence, there in a need for systems directed to analytics of a battery in an energy storage system in order to determine the state of health (SoH) of the battery based upon observable data and phenomena. The battery analytics technologies disclosed herein estimate the SoH of a battery by analyzing data from at least one sensor that observes the phenomena of current flowing to or from the battery or other components of the energy storage system, as well as by analyzing the state of charge estimate from an associated battery management system, provided manufacturer information or determined from the observable data.

By, for example, “coulomb counting” in which the charge transferred through the battery during a charge/discharge process is counted by monitoring the input and output current continuously, the battery analytics technologies of the energy storage system are able to determine a rate of amps per hour, which is then compared to a remaining capacity of the battery estimate to determine a state of charge differential from the initial battery capacity of the battery module to the determined state of health of the battery module.

In a first example, an energy storage system 100 includes a plurality of energy storage nodes 110A-N and a control system 105. Each of the plurality of energy storage nodes 110A-N includes a plurality of battery modules 412A-N. The control system 105 includes at least one processor coupled to the plurality of energy storage nodes 110A-N and memory configured to receive or store data and programming. The at least one processor of the control system 105 is configured to perform operations in accordance with execution of the programming, obtain an initial battery capacity (Cᵢ) and an initial state of charge (SoC₀) for at least one battery module 412A of the plurality of battery modules 412A-N, and control at least one sensor 255 to measure and record electrical current flow between multiple components to provide raw data 599 for electrical current within the energy storage system 100. The at least one processor is further configured to determine a present state of charge (SoC₁) of the least one battery module 412A over an elapsed time for the predetermined period, and determine an integrated current value based upon the measured raw data for the electrical current over the elapsed time. The processor determines a remaining capacity of the at least one battery module 412A at an end of the elapsed time. The processor further determines an estimated state of health (SOH) of the at least one battery module 412A based upon the initial battery capacity (C) and the determined remaining capacity including the integrated current value.

In a second example, a method includes obtaining an initial battery capacity (Cᵢ) and an initial state of charge (SoC₀) for at least one battery module 412A of a plurality of battery modules 412A-N and controlling at least one sensor 255 to measure and record electrical current flow between multiple components to provide raw data 599 for electrical current within the energy storage system 100. The method further includes determining a present state of charge (SoC₁) of the least one battery module 412A over an elapsed time for a predetermined period, and determining an integrated current value based upon the measured raw data for the electrical current over the elapsed time. The method further includes determining a remaining capacity of the at least one battery module 412A at an end of the elapsed time and determining an estimated state of health (SOH) of the at least one battery module 412A based upon the initial battery capacity (Cᵢ) and the determined remaining capacity including the integrated current value.

In a third example, a non-transitory computer-readable medium 613, 653 includes a battery state of health (SOH) modules 500. Execution of the battery SOH module 500 by one or more processor 612, 652 configures one more computing devices 105, 108 to obtain an initial battery capacity (Cᵢ) and an initial state of charge (SoC₀) for at least one battery module 412A of a plurality of battery modules 412A-N, control at least one sensor 255 to measure and record electrical current flow between multiple components to provide raw data 599 for electrical current within the energy storage system 100, and determine a state of charge (SoC₁) of the least one battery module 412A over an elapsed time for a predetermined period. The computer devices 105, 108 are further configured to determine an integrated current value based upon the measured raw data for the electrical current over the elapsed time. Further, the computer devices 105, 108 are configured to determine a remaining capacity of the at least one battery module 412A at an end of the elapsed time and determine an estimated state of health (SOH) of the at least one battery module 412A based upon the initial battery capacity (Cᵢ) and the determined remaining capacity including the integrated current value.

Additional objects, advantages and novel features of the examples will be set forth in part in the description which follows, and in part will become apparent to those skilled in the art upon examination of the following and the accompanying drawings or may be learned by production or operation of the examples. The objects and advantages of the present subject matter may be realized and attained by means of the methodologies, instrumentalities and combinations particularly pointed out in the appended claims.

### BRIEF DESCRIPTION OF THE DRAWINGS

The drawing figures depict one or more implementations in accordance with the present concepts, by way of example only, not by way of limitations. In the figures, like reference numerals refer to the same or similar elements.

FIG. 1A is an isometric view of a battery energy storage system that includes multiple energy storage nodes, a central control system element, and an external grid.

FIG. 1B is an isometric view of a single energy storage node, multiple optional energy storage nodes, and an external grid.

FIG. 2 is an electrical diagram of a battery energy storage system similar to that of FIGS. 1A-B depicting information and working power flows.

FIG. 3 is a system diagram of a battery energy storage system similar to that of FIGS. 1A-B depicting step-up converter controllers and the distributed nature of a battery energy storage system.

FIG. 4 is an isometric translucent view of the energy storage node of FIG. 1B that includes a battery bank of multiple battery modules.

FIG. 5 is a flowchart of the battery state of health analytics protocol.

FIG. 6 is a high-level functional block diagram of the energy storage system of FIGS. 1A and 1B that depicts components of the control system and the energy storage nodes to control power flow, overall operations, and implementation of a state of health protocol.

### PARTS LISTING

100 Battery Energy Storage System
102 Energy Source
104 Power Conversion System (PCS)
105 Central Control System Element
106 Connected Load
108 Control Subsystem
109A-N Battery Data
110A-N Energy Storage Nodes
111 Energy Storage Element
112 Required Power Flow
113 External Grid
114A-C Distributed PCS
115 Overall Operations
150 Battery Array
155A-C Battery Core
200 Battery Energy Storage System
211 Core Controller
212 Power Plant Controller
251 High Voltage (HV) Bus
252 Medium Voltage (MV) Bus
254 Point of Connection (POC)
255 Data Collection Sensors
256A-N Meter Readings
257 HV/MV Transformer
258A-X Core Transformer
259A-X Core Transformer
260A-X MV Circuit Breaker (CB_Core)
261 HV Circuit Breaker (CB_HV)
262 Array
410A-F Battery Strings
412A-N Battery Modules
413 Battery Bank
500 Battery State of Health (SoH) Protocol
605 Network
610 Physical Space
611 Network Communication Interface
612 Processor
613 Memory
616 A-N Battery Conditions
651 Network Communication Interface
652 Processor
653 Memory
BMS Battery Management System
APS Apparent Power System Controller
Node SDU Node Storage Dispatch Unit
MDU Market Dispatch Unit
RTAC Real Time Automation Controller

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, transfer functions, and/or circuitry have been described at a relatively high-level, without detail, in order to avoid unnecessarily obscuring aspects of the present teachings.

The term “coupled” as used herein refers to any logical, physical, electrical, or optical connection, link or the like by which electricity, power, signals or light produced or supplied by one system element are imparted to another coupled element. Unless described otherwise, coupled elements or devices are not necessarily directly connected to one another and may be separated by intermediate components, elements, or communication media that may modify, manipulate, or carry the electricity, power, light or signals.

Unless otherwise stated, any and all measurements, values, ratings, positions, magnitudes, sizes, angles, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as ±5% or as much as ±10% from the stated amount. The terms “approximately,” “significantly,” or “substantially” means that the parameter value or the like varies up to ±25% from the stated amount.

The orientations of the battery nodes, cores, arrays, racks, elements, modules, submodules, strings, banks, or cells; associated components; circuits; and/or any complete devices, such as battery energy storage systems, combined energy storage systems, or modular energy storage systems, incorporating battery nodes, racks, elements, modules, submodules, strings, banks, or cells such as shown in any of the drawings, are given by way of example only, for illustration and discussion purposes. In operation for a particular battery energy storage application, a battery node, core, array, rack, element, module, submodule, string, bank, or cell may be oriented in any other direction suitable to the particular application of the battery energy storage system, for example upright, sideways, or any other orientation. Also, to the extent used herein, any directional term, such as left, right, front, rear, back, end, up, down, upper, lower, top, bottom, and side, are used by way of example only, and are not limiting as to direction or orientation of any energy storage system or battery nodes, racks, elements, modules, submodules, strings, banks, or cells; or component of an energy storage system or battery node, rack, element, module, submodule, string, bank, or cell examples illustrated in the accompanying drawings and discussed below.

Unless otherwise indicated, any multiplicity of components, such as energy storage nodes 110A-N, battery strings 410A-F, or battery modules 412A-N can include any number of said components, including as few as one, and are not limited by the depicted number of components. Unless otherwise indicated, any coupled electrical components can be linked in series or in parallel. In the case of energy storage nodes 110A-N or battery modules 412A-N, the component may be linked in both series and/or in parallel, depending upon the state of the switch or submodule.

Reference now is made in detail to the examples illustrated in the accompanying drawings and discussed below.

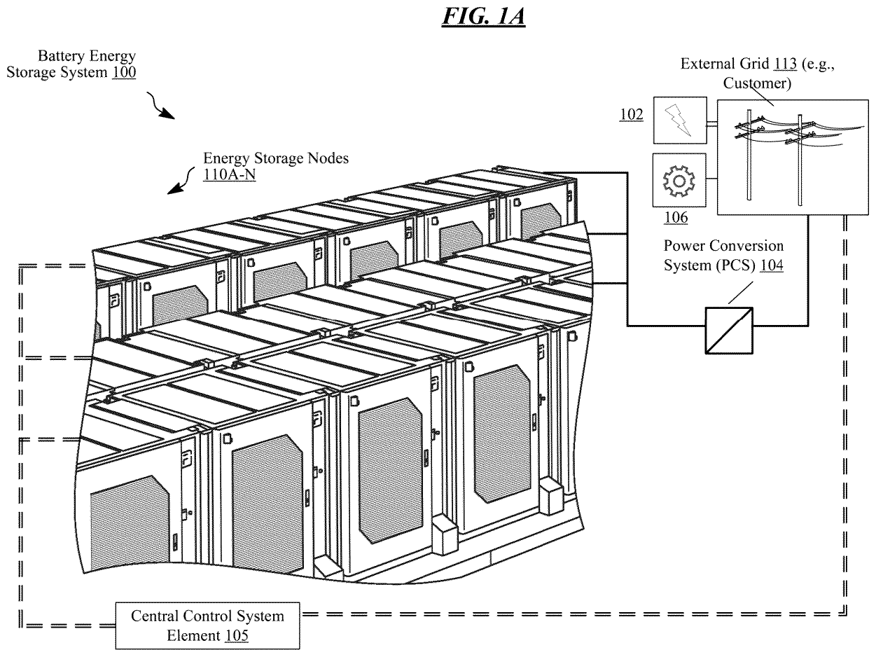

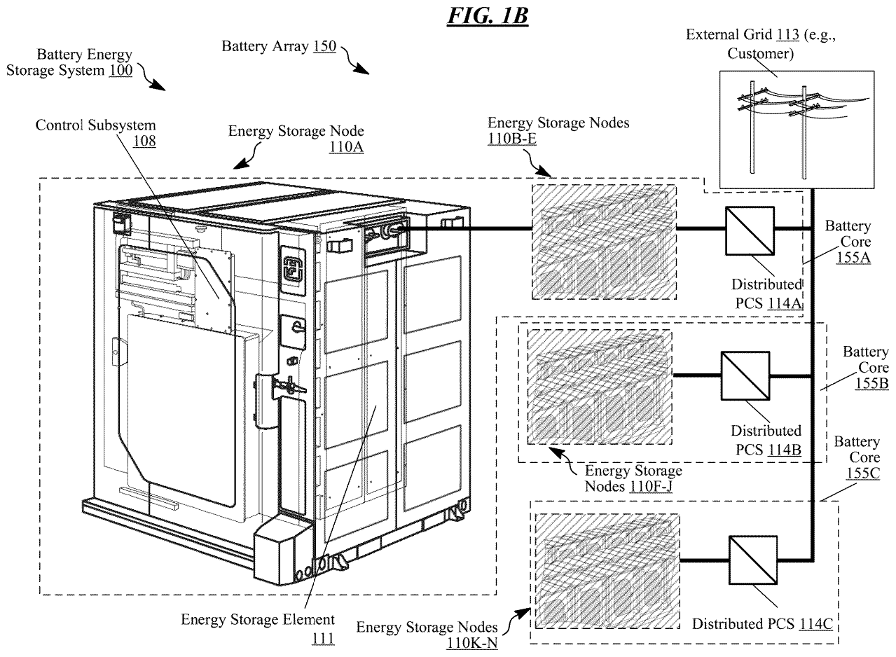

FIG. 1A is an isometric view of an energy storage system, for example, a battery energy storage system (BESS) 100 that includes multiple energy storage nodes 110A-N, a central control system element 105, and an external grid 113. The battery energy storage system 100 includes multiple energy storage nodes 110A-N optionally connected to a power conversion system (PCS) 104. The energy storage nodes 110A-N include batteries of any existing or future reusable battery technology including, for example, lithium ion, flow batteries, or mechanical storage such as flywheel energy storage, compressed air energy storage, pumped storage hydroelectricity, gravitational potential energy, or a hydraulic accumulator. The energy storage nodes 110A-N, collectively and individually, are capable of providing direct current electricity to an external load, for example, connected load 106, and thereby discharging, as well as are capable of receiving direct current electricity from an external source, for example, energy source 102, and thereby charging.

The energy source 102 can be part of any suitable system for producing electrical energy. In an example, the system can be a renewable energy system in which the energy source 102 can be replenished. Such a renewable energy source 102 can include solar power, wind power, geothermal power, biomass, and hydroelectric power. For example, the renewable energy system can be implemented as an array of photovoltaic modules. The photovoltaic (PC) modules can include crystalline silicon, amorphous silicon, copper indium gallium selenide (CIGS) thin film, cadmium telluride (CdTe) thin film, and concentrating photovoltaic which uses lenses and curved mirrors to focus sunlight onto small, but highly efficient, multi-junction solar cells. In another example, the energy system for the energy source 102 can be a non-renewable energy system in which the energy source 102 includes a non-renewable energy source, such as a fossil fuel.

To facilitate providing and receiving direct current, the energy storage nodes 110A-N can be connected to the power conversion element 104. The power conversion system 104 is configured to standardize power inputs and outputs to and from the energy storage nodes 110A-N such that the power inputs and outputs are made consistent or uniform for desired operations or an environment of the battery energy storage system (BESS). The power conversion system 104 can be comprised of: (1) an inverter, converting the DC source of the energy storage nodes 110A-N to an AC waveform, and vice versa; (2) a DC/DC converter, converting the DC source of the energy storage nodes 110A-N to a different DC source characteristic; (3) other known power conversion elements; or (4) a combination thereof.

When the energy storage nodes 110A-N provide direct current, the power conversion system 104 transforms the direct current into alternating current for use by the external grid 113 and normalizes the amperage from battery modules (not pictured) of the energy storage nodes 110A-N to the external grid 113. Additionally, when the energy storage nodes 110A-N require direct current, the power conversion system 104 transforms alternating current into direct current from the external grid 113 and normalizes the amperage from the external grid 113 to the energy storage nodes 110A-N. As shown in FIG. 1B, the energy storage nodes 110A-N may be coupled in groups to a distributed power conversion system 114A-114C, which may perform some or all of the tasks of a power conversion system 104 and may obviate entirely the use of the power conversion system 104.

The battery energy storage system 100 including the energy storage nodes 110A-N (and the power conversion system 104 and when the power conversion system 104 is not omitted) is depicted with a single connection to the external grid 113. In scenarios where the external grid 113 is complex and connects to multiple energy sources 102 and connected loads 106, such as a power grid with consumption devices, a single connection to the battery energy storage system 100 can either absorb energy produced by the energy sources of the external grid 113 in excess of the demand of the connected loads of the external grid 113, or provide energy to the connected loads of the external grid 113 in excess of the capacity of the energy sources of the external grid 113. Alternatively, separate lines may run to a segregated energy source as well as to connected loads or the external grid 113. Separate lines may be advantageous in scenarios where the segregated energy source is inconsistent, such as a wind or solar-based energy source. In such scenarios, the power from the energy source is pushed to the energy storage modules 110A-N, which then either charge or discharge, and provide consistent energy to the connected loads or external grid 113 via another electrical route.

An energy source 102 can be any suitable system for producing electrical energy, such as a turbine or photovoltaic cell. The external grid 113 can include a power grid or a smaller local load such as a backup power system for a facility such as a hospital, manufacturing site, residential home, or other suitable facility.

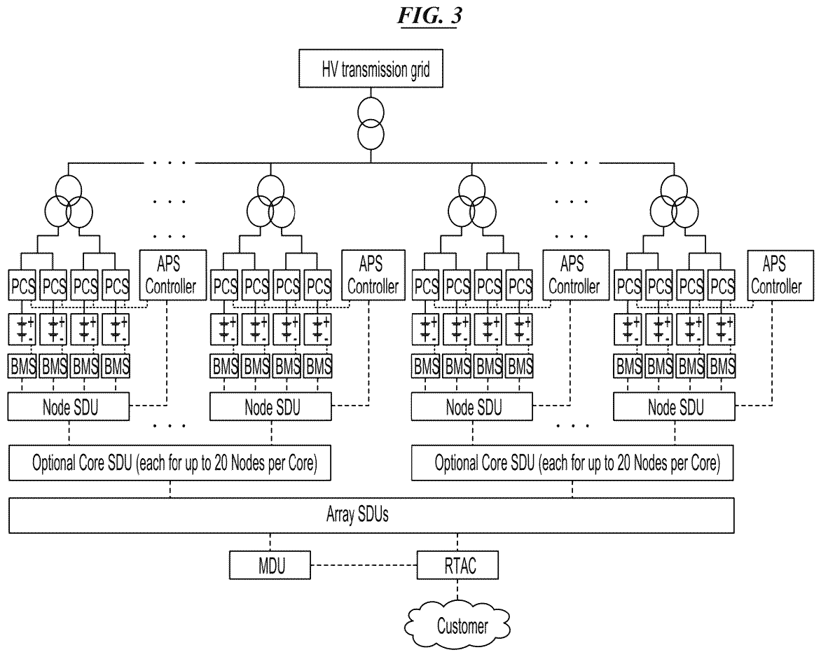

The power conversion system 104 can facilitate normalizing input or output wattage or voltage, in order to provide consistent output and protect the energy storage nodes 110A-N or external grid 113 from damage. The power conversion system 104 may perform this normalization in concert with a central control system element 105 including at least one processor. The central control system element 105 also communicates with and controls the energy storage nodes 110A-N in order to adjust electrical output, as well as electrical capacity or intake of the energy storage nodes 110A-N. The central control system element 105 has components, such as those depicted in FIG. 3 which operate independently at their respective levels. Therefore, the central control system element 105 and the distributed control system elements 114A-114C (e.g., BMSs, APS controllers, SDUs, MDUs, and RTAC (see FIG. 3)) are configured to operate in a combination of independent and centralized operation.

Generally, the energy storage nodes 110A-N of the battery energy storage system 100 connected to the external grid 113 operate in concert: either providing power to the external grid 113 and discharging or receiving power from the external grid 113 and charging. This concerted effort is coordinated by the central control system element 105, and other control units such as market dispatch units (MDUs) or real-time automation controllers (RTACs), illustrated in FIG. 3. Further methods and systems related to the management and maintenance of the energy storage nodes 110A-N (e.g., battery modules 412A-N) of the battery energy storage system 100 are disclosed in U.S. application Ser. No. 17/810,983, filed on Jul. 6, 2022 (now U.S. Pat. No. 11,789,086, issued Sep. 27, 2023), titled “Cell and Rack Performance Monitoring System and Method,” the entirety of which is incorporated by reference herein.

FIG. 1B is an isometric view of an energy storage node 110A, multiple optional energy storage nodes 110B-N, and an external grid 113. The energy storage node 110A includes an energy storage element 111.

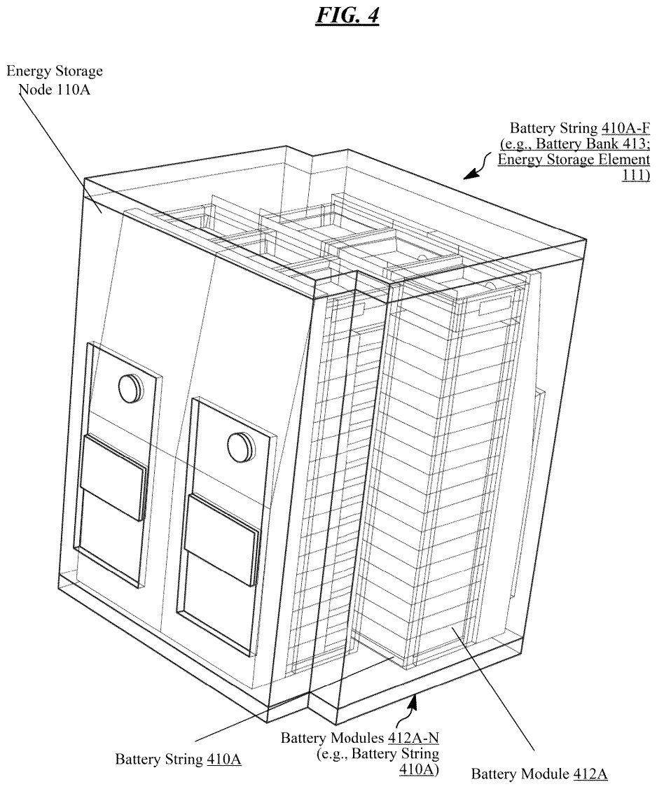

The energy storage element 111 can include: (1) a single battery cell; (2) a cell grouping, including several battery cells in parallel configuration; (2) a battery submodule or module 412A (see FIG. 4), including several battery cells in parallel and serial configuration; (4) a battery string 410A (see FIG. 4), including several battery modules 412A-N in series; (5) a battery bank 413 (see FIG. 4), including several battery strings 410A-F in parallel; (6) other known energy storage elements; or (7) a combination thereof.

The energy storage node 110A can include, for example, HVAC heating or cooling elements to regulate the temperature of the energy storage node 110A, in particular the energy storage element 111.

The energy storage nodes 110A-N are organized into collections of nodes 110A-E, 110F-J, 110K-N, each collection paired with a distributed power conversion system 114A-C. A grouping of nodes 110A-E with a distributed power conversion system 114A constitutes a battery core 155A.

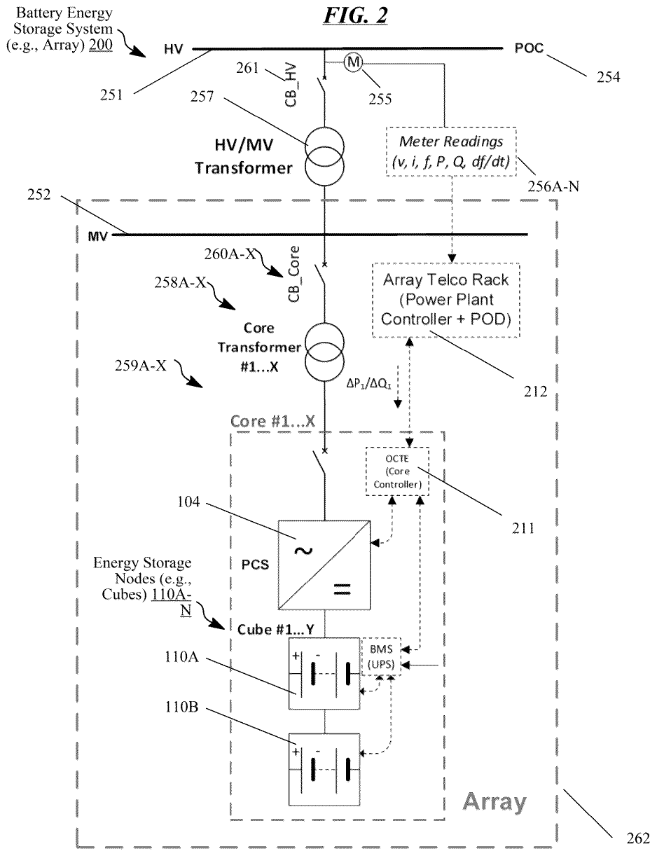

The distributed power conversion system 114A-C can include: (1) an inverter, converting the DC source of the energy storage element 111 to an AC waveform, and vice versa; (2) a DC/DC converter, converting the DC source of the energy storage element 111 to a different DC source characteristic; (3) other known power conversion elements; or (4) a combination thereof. The distributed power conversion systems 114A-C can service an individual energy storage node 110A, or any number of energy storage nodes 110A-N. Multiple energy storage nodes 110A-N are generally arranged in series, although other wiring sequences are contemplated. A distributed power conversion system 114A servicing multiple energy storage nodes 110A-E can be a battery core 155A, and can be controlled by a core controller 212 (see FIG. 2). The core controller 212 can coordinate with a node controller present in each associated energy storage node 110A-E.

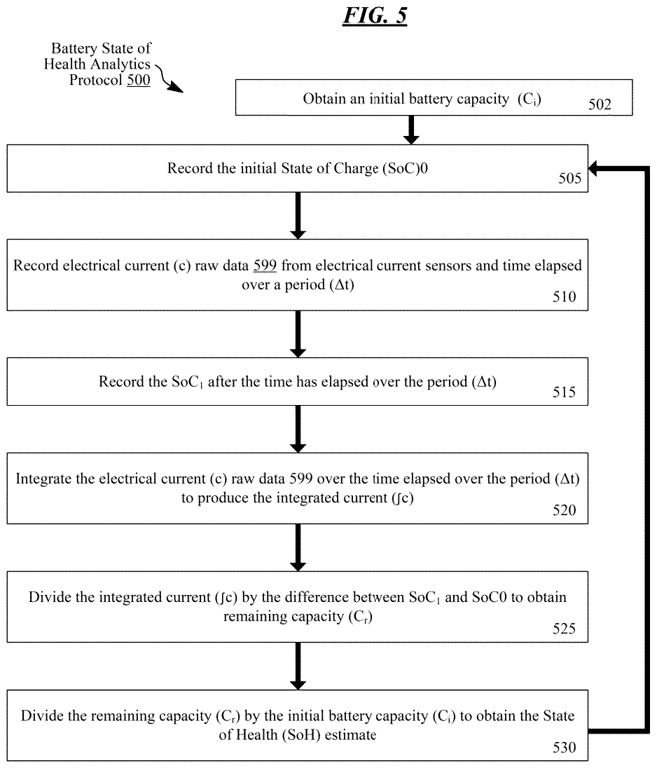

Physical data collection sensors and data logging can be used throughout the battery energy storage system 100, to collect operational and environmental data, in particular current flow between components, from the components of the battery energy storage system, such as the energy storage node 110A, and the distributed PCSs 114A-C to produce raw data 599 (see FIG. 5).

FIG. 2 is an electrical diagram of a battery energy storage system 200 similar to the battery energy storage system 100 of FIG. 1 depicting information and working power flows.

The battery energy storage system 200 connects to an electrical grid, including both an energy source 102 and a connected load 106, via a point of connection (POC) 254. The POC 254 is coupled to a high voltage (HV) bus 251, which is an electrical bus rated and intended for high voltage matching the voltage expected by the electrical grid. The HV bus 251 can allow for multiple battery energy storage systems 200 or power storage or generating facilities to be linked in series or in parallel before connecting to an electrical grid via the POC 254.

The battery energy storage system 200 includes an HV circuit breaker 261, designed to selectively isolate the remainder of the battery energy storage system 200 from the HV bus 251. The HV circuit breaker 261 may be hardwired to trip under certain circumstances, or the HV circuit breaker 261 may be controlled by the power plant controller 212 or other controllers.

An HV/medium voltage (MV) transformer 257 is coupled between the HV bus 251 and an MV bus 252. The HV/MV transformer 257 steps the voltage experienced at the HV bus 251 connection end down to the voltage expected at the MV bus 252 connection end, as well as stepping up the voltage from the MV bus 252 connection end to the voltage expected at the HV bus 251 connection end.

The MV bus 252 is within the bounds of the array 262. The array 262 includes a power plant controller 212 to facilitate operation of one or more cores 259A-X. While multiple arrays may be coupled in series or in parallel to the MV bus 252, in this example only a single array 262 with a single power plant controller 212 is depicted.

A core 259A is coupled to the MV bus 252 by a core transformer 258A and a core circuit breaker 260A. Multiple cores 259A-X are connected to a single MV bus 252, each with a respective core transformer 259A-X and respective core circuit breaker 260A-X: in this figure, only a single core 259A is depicted in detail.

The MV circuit breaker 260A is designed to selectively isolate the remainder of the core 259A from the MV bus 252. The MV circuit breaker 260A may be hardwired to trip under certain circumstances, or the MV circuit breaker 260A may be controlled by the power plant controller 212, the core controller 211, or other controllers.

The core transformer 258A is coupled between the MV bus 252 and the core 259A. The core transformer 258A steps the voltage experienced at the MV bus 252 connection end down to the voltage expected at the core 259A connection end, as well as stepping up the voltage from the core 259A connection end to the voltage expected at the MV bus 252 connection end.

The core 259A includes the power conversion system 104, which includes all hardware and controls to convert bi-directionally between direct current (DC) and alternating current (AC) power. The power conversion system 104 provides AC power to and from the MV bus 252, and provides DC power to and from the cubes 110A-N.

At least one data collection sensor, for example, meter 255, is connected near the HV bus 251 for the purpose of collecting at least measured values relevant to oscillation determinations: instant voltage, current, as well as power frequency, instant power, and the rate of change of frequency, are all values that can inform the power plant controller 212 and the POD controller 105 in dampening power oscillations.

The meter readings 256A-N are collected continuously or periodically by the meter 255, and are provided to the power plant controller 212.

Physical data collection sensors and data logging can be used throughout the battery energy storage system 200, to collect operational and environmental data 255A-N, in particular current flow between components, from the components of the battery energy storage system, such as the HV/MV transformers 257, core transformers 258A-X; cores 259A-X; buses 251, 252; meter 255, and controllers 212, 211 to produce raw data 599 (see FIG. 5).

FIG. 3 is a system diagram of a battery energy storage system similar to that of FIGS. 1A-B depicting step-up converter controllers and the distributed nature of a battery energy storage system. Energy storage nodes are electrically connected to power conversion systems (PCSs), which are then electrically connected together via a bus, then electrically connected via a three-winding transformer to another bus, which then electrically connects to the HV voltage grid via a transformer. The energy storage nodes are controlled by battery management systems (BMSs), which, along with the PCSs, communicate with apparent power system controllers (APSs). The APSs and the BMSs communicate with node storage dispatch units (SDUs). Node SDUs interface with and monitor the connected BMSs, PCSs and other hardware to higher level controls. The node SDUs communicate with core SDUs, which dispatch real and reactive power to the Nodes based on their operation conditions, as well as provide telemetry values to the node SDUs, and provide the array SDU and node SDUs with core-level system operation data. The core SDUs communicate with the array SDU, which provides a market dispatch unit (MDU) and real-time automation controller (RTAC) with measurements and system operation data. The array SDU also dispatches real and reactive power to the core SDUs based on core-level stored energy. The MDU executes real and reactive power applications, while the RTAC communicates with customer control systems utilizing adjustable various interfaces.

Physical data collection sensors and data logging can be used throughout the battery energy storage system, to collect operational and environmental data, in particular current flow between components, from the components of the battery energy storage system, such as the energy storage nodes, PCSs, BMSs, APSs, node SDUs, core SDUs, array SDU, MDU, and RTAC, to produce raw data 599 for electrical current within the energy storage system for a predetermined period of time (see FIG. 5).

FIG. 4 is an isometric translucent view of the energy storage node 110A of FIG. 1B that includes a battery module 412 of multiple battery modules 412A-N. The energy storage node 110A stores a plurality of battery strings 410A-F as a battery bank 413 and as an energy storage element 111. The energy storage node 110A is both a physical housing of energy storage element 111, as well as a logical and electrical collection of the battery bank 413 that constitutes energy storage element 111. The energy storage node 110A physically houses the battery bank 413, and the electrical performance of the battery bank 413 comprising the energy storage element 111 may be attributed to the energy storage node 110A itself. For example, if a battery string 410A of the battery bank 413 is able to store one hundred and two kilowatt hours of energy, and the battery bank 413 contains six battery strings 410A-F, then the energy storage node 110A (as well as the energy storage element 111) may be understood to be described as storing six hundred and twelve kilowatt hours of energy. An energy storage node 110A, energy storage element 111, and battery bank 413 may contain greater or fewer numbers of battery strings 410A-F than depicted in the figure.

A given battery string 410A contains multiple battery modules 412A-N. Much like the relationship between the energy storage node 110A and contained battery bank 413, the battery string 410A is both a physical collection of battery modules 412A-N as well as a logical and electrical collection of battery modules 412A-N. As an example, if a battery module 412A is able to store six kilowatt hours of energy, and the battery string 410A contains seventeen battery modules 412A-N, then the battery string 410A may be understood to and be described as storing one hundred and two kilowatt hours of energy. A battery string 410A may contain greater or fewer numbers of battery modules 412A than depicted in the figures.

As the battery string 410A is a logical and electrical collection of battery modules 412A-N, the collection is not necessarily defined by the physical structure or ordering of the battery modules 412A-N, other than the constituent battery modules 412A-N in this example are wired in series. Therefore, the battery string 410A may be alternatively described as a battery rack, a battery sub-rack, or a battery array: each of these terms (element, rack, sub-rack, array) can be categories of battery string 410A: a battery string 410A is the logical and electrical collection of battery modules 412A-N, without explicit regard for physical structure or ordering of the battery modules 412A-N, other than in this particular example wiring in series. In some implementations, a finer level of encapsulation exists within the battery module 412A, which may be identified as a battery grouping within the battery module 412. Those battery groupings may also include a finer level of encapsulation, which may be identified as a battery cell within the battery grouping, comprising prismatic, pouch, or cylindrical battery cells.

In this example, the energy storage node 110A represents a single physical fixture, which may be limited in maximum size by the mass or volume a person, forklift, or vehicle is capable of transporting as a singular, atomic unit. The battery bank 413 within the battery module 110A represents a physical organizational structure for organizing and wiring battery cells, groupings, battery modules 412A-N, and battery strings 410A-F within the energy storage node 110A. A battery cell is generally the largest unit of manufacture a battery producer can produce capable of charging and discharging electricity at a chemical level. In some examples battery cells are packaged together as battery modules 412A-N, representing the smallest unit a particular operator would remove or replace in the battery energy storage system 100: in examples where multiple battery cells are packaged together, the individual battery cells are too small or sensitive to perform on-site particularized maintenance, and instead the entire package of battery cells (e.g., a battery module 412A) is either collectively repaired or replaced.

The energy storage nodes 110A may resemble the features presented in the energy storage system described in International Application No. PCT/US2021/30551, filed on May 4, 2021 (published as WO201226011 on Nov. 11, 2021), titled “Energy Storage System with Removable, Adjustable, and Lightweight Plenums,” the entirety of which is incorporated by reference herein.

Physical data collection sensors and data logging can be used throughout energy storage node 110A, to collect operational and environmental data, in particular current flow between components, from the components of the energy storage node 110A, such as the battery cells, battery modules 412A-N, battery strings 410A-F, and battery bank 413 to produce raw data 599 (see FIG. 5).

FIG. 5 is a flowchart of the battery State of Health (SoH) analytics protocol 500. The battery SoH analytics protocol 500 can be implemented across an entire battery energy storage system (BESS) 100, or on a subset of components, such as a core 259A. The battery SoH analytics protocol 500 can be implemented in a single device, represented by the control system element 105, or in a distributed manner across the BMSs, SDUs, MDU and RTAC of FIG. 3.

The battery SoH analytics 500 operates on the principle that when a battery system (e.g., energy storage node 110A) is discharging or charging, the state of charge estimate for the battery system can be updated based on a process called “coulomb counting”. In “coulomb counting,” a battery's state of charge (SoC) is determined/monitored by measuring the charge that flows in and out of the battery during charge-discharge cycle. Coulomb counting includes taking the integral of data from a current sensor, for example, meter 255, resulting in a first value (integrated current (∫c)) with units of amps*hours. The first value is then divided by an estimate of the remaining capacity of the battery, which also has units of amps*hours. The estimate of the remaining capacity and an initial battery capacity Cᵢ can be provided by the energy storage node 110A, or a BMS as in FIG. 3, or any of the disclosed interconnected systems which may be provisioned with access to the maximum or minimum charge voltages of the battery system. The present state of charge (SoC)₁ is then calculated as SoC_1=SoC_0+([integrated current (∫c)]/remaining capacity), or the present state SoC₁ is equal to the initial SoC₀ plus the first value divided by the remaining capacity. Remaining capacity is equal to the SoH*initial capacity, meaning the SoH is equal to the initial capacity divided by the remaining capacity.

Therefore, by observing how the BMS or energy storage node 110A updates the SoC (as the initial SoC₀ proceeds to the present SoC₁) as the battery system operates, an alternate estimate of SoH can be derived. This determined estimate of SoH is likely to be more accurate than the “standard” SoH estimate normally provided by the BMS, as the BMS uses the underlying values in this alternate SoH estimate for SoC state estimation, which the manufacturer of the battery or BMS is much more likely to ensure is accurate. Inaccurate SoC estimates can lead to overcharging or undercharging the battery, which results in a “bad” product that stores less energy than advertised if undercharging, or potentially catastrophically fails if overcharging. Therefore, the designer of the BMS or energy storage node 110A is highly motivated for the SoC parameter estimate to be accurate.

To facilitate these principles, a control system such as the central control system element 105 comprises at least one processor that operates programming such as the battery SoH analytics protocol 500 of FIG. 5 and performs the following operations. At block 502, an initial battery capacity (Cᵢ) of at least one battery module of the energy storage node 110A is obtained, for example, from the manufacturer of the Battery Management System (BMS) or the battery. In block 505, the battery SoH analytics protocol 500 records the initial State of Charge (SoC)₀ provided, for example, by the Battery Management System (BMS). The SoC₀ and initial battery capacity (Cᵢ) can be stored, for example, in the BMS, or in a memory coupled to the energy storage node 110A—if stored in the energy storage node 110A, these data points and all of the following data points in the protocol may be sent to a BMS for SoH analysis, or the SoH analysis can be performed on-board the energy storage node 110A. The SoC₀ and initial battery capacity (Cᵢ) may be accessed from the storage at the same time or separately during implementation of the battery SoH analytics protocol 500.

At block 510, at least one sensor is controlled to measure and record electrical current flowing between the components of the energy storage system to provide raw data 599 of the electrical current within the energy storage system for a predetermined period of time (Δt), for example, one hour. The electrical current can be measured anywhere in the BESS 100, but measuring closer to the battery (e.g., the energy storage node 110A) can result in more accurate SoH conclusions than estimating current at the battery based on electrical current measured elsewhere in the BESS 100. Additionally, the measurements can be performed at the rack, module, cell, etc. level of the energy storage node 110A, providing a particularized SoH conclusion to that particular level and instance of energy storage.

In block 515, after some time has elapsed of the predetermined period of time (Δt) and the battery has partially charged or discharged, the battery SoH analytics protocol 500 then determines and records the SoC₁ after the time has elapsed over the period. Meaning, if the period of block 510 is ten minutes, then the SoC₁ will be recorded after the electrical current raw data 599 has been recorded for ten minutes.

The battery SoH analytics protocol 500 in block 520 integrates the electrical current raw data 599 over the period of time elapsed, which will produce an integrated current value (∫c). Then in block 525, the integrated current value is divided by the difference between the SoC₁ from block 515 and the initial SoC₀ from block 505 to obtain the remaining capacity (Cᵣ) of the battery (Cᵣ=∫c/(SoC₁−SoC₀)).

In block 530, the remaining capacity from block 525 is divided by the initial battery capacity (Cᵢ), which results in a State of Health (SoH) estimate that provides information on the battery's general health that is useful for life expectancy and potential replacement timelines for the battery or other components of the system. For example, an adjustment for at least one of maintenance, a repair or a replacement schedule for the battery module may be based upon the estimated state of health (SoH).

After the estimated state of health (SoH) is determined, the flow and implementation of the Battery State of Health Protocol 500 may return to block 505 multiple times during a given charging or discharging cycle, in order to verify or fine tune the SoH estimate over the course of the charging cycle. In some scenarios in which there are multiple SoH estimates, the worst-case SoH estimate value is used as a reported SoH estimate—in others, the multiple SoH estimates may be aggregated by some means (e.g., averaging, removing outliers, determining median, etc.) to obtain the reported SoH estimate. The time elapsed may be weighed in aggregating multiple SoH estimates.

Once an accurate SoH estimate exists for a given battery, as stated above, operators of the BESS 100 can prepare a maintenance, repair, or replacement schedule based on the SoH estimate; or adjust/revise an existing maintenance, repair, or replacement schedule; or adjust billing for capacity of the given battery; or revise a bidding strategy to provide energy from storage, or to purchase energy from the grid 113.

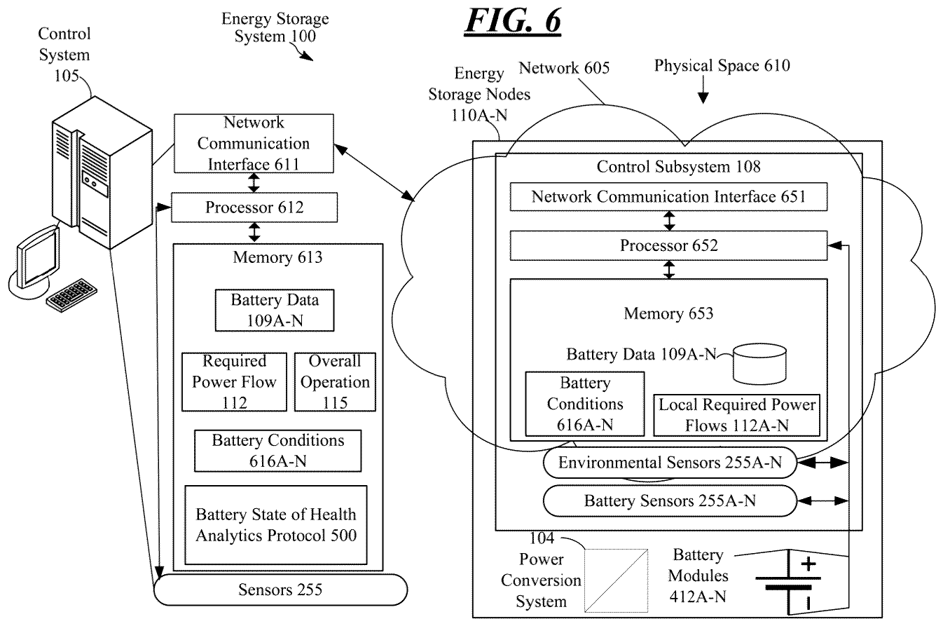

FIG. 6 is a high-level functional block diagram of the energy storage system of FIGS. 1A and 1B that depicts components of the control system 105 and the energy storage nodes 110A-N to control power flow 112, overall operations 115 and implementation of a state of health (SOH) protocol 500.

The plurality of energy storage nodes 110A-N includes an energy storage element 111 including a plurality of battery modules 412A-N, a power conversion system 104, and a control subsystem 108 to receive battery data 109A-N from environmental and battery sensors 255A-N, the battery modules 412A-N, the power conversion system 104, or a combination thereof.

The control system 105, energy storage nodes 110A-N, external grid 113, and other components of the system 100 can be in communication over a network 605 or one or more networks 605A-N. The networks 605A-N can be a local area network, wide area network, or a combination thereof. For example, the control system 105 can be coupled via a local area network to the energy storage nodes 110A-N and the external grid 113. Alternative or additionally, the control system 105 can be coupled via a wide area network to the energy storage nodes 110A-N and external grid 113. Or the control system 105 can be coupled via a combination of networks, such as via a local area network to components of the energy storage system 100, including the energy storage nodes 110A-N, and coupled via a wide area network to the external grid 113.

Control system 105 may include a network communication interface 611 configured for wired or wireless communication over the network 605. The control system 105 further includes a memory 613, and a processor 612 coupled to the network communication interface 611 and the memory 613. As shown in FIG. 6, the memory 613 is configured to store battery data 109A-N, a required power flow 112, overall operations 115, and battery conditions 616A-N. The control system 105 can also include sensors 255 coupled to the processor 612 to detect or monitor various system parameters, such as power, temperature, voltage, current, resistance, and/or impedance. For example, the sensors 255 can be coupled to the HV bus 251 illustrated in FIG. 2.

Control system 105 is configured to receive or store information related to, for example, a required power flow 112 or an overall operations 115 for the energy storage system 100. The required power flow 112 can include an active power, a reactive power, or a total system power discharge or charge requirement. The required power flow 112 can be a power command for the external grid 113 based on a customer or independent system operator request received over the network 605 from the external grid 113, in which case the power command is externally determined.

The overall operations 115 can be a power command for the external grid 113 based on parameters in a customer or independent system operator request or market data received over the network 605 from the external grid 113. The control system 105, control subsystem 108, or both can take the parameters of the overall operations 115 and attempt to best implement the overall operations 115. In this case, the power command to achieve the overall operations 115 is internally determined by the control system 105, for example, based on satisfying the customer or independent system operator request for the external grid 113.

Control system 105 can take the required power flow 112 needed for the external grid 103, for example, as requested by a customer or software application or required during the bid into market or otherwise operate asset to promote calibration or balancing, as discussed above in blocks 520 and 525 of FIG. 5.

Energy storage nodes 110A-N include a control subsystem 108, battery modules 412A-N, and a power conversion system 104. Control subsystem 108 of the energy storage nodes 110A-N includes a network communication interface 651 configured for wired or wireless communication over the network 605. The control subsystem 108 further includes a memory 653, and a processor 652 coupled to the network communication interface 651 and the memory 653. As shown in FIG. 6, the memory 653 may be configured to store battery data 109A-N, battery conditions 616A-N, and local required power flows 112A-N.

The control subsystem 108 further includes environmental sensors 255A-N and battery sensors 255A-N coupled to the processor 652. Environmental sensors 255A-N can measure, for example, humidity and temperature inside of an enclosure of the energy storage nodes 110A-N. Battery sensors 255A-N can include, for example, a voltage sensor, a current sensor, and a temperature sensor to measure readings of battery data 109A-N, such as a voltage, a current, a temperature, or other physical phenomena occurring within the battery modules 412A-N.

In addition to determining an implementation of the battery state of health protocol 500 (see, FIG. 5) for a component of interest within the energy storage system 100, the control subsystem 108 or the control system 105 may be further configured to determine at least one battery condition 616A-O about one or more of the energy storage nodes 110A-N from the battery data 109A-N. Battery conditions 616A-N can be algorithmically determined estimates from battery data 109A-N, readings from the sensors 255A-N that monitor various system parameters on, for example, the HV bus 251, or a combination thereof.

Some battery conditions 616A-N can be inputted by an operator of the energy storage system 101 into a software application on a separate computing device that is coupled to the control system 105 or the control subsystem 108 over the network 605, and used, for example to determine state of charge. Alternatively, a battery management system (BMS) or the control subsystem 108 can derive a state of charge from the measured raw data 599.

Each of the energy storage nodes 110A-N can include the power conversion system 104 for controlling the respective one of the local required power flows 112A-N. The battery data 109A-N can include a voltage, a current, a temperature, or other physical phenomena occurring within the battery module 412A, or a combination thereof.

The battery energy storage system 100, energy storage nodes 110A-N, power conversion system 104, and various controllers may rely on a processor, such as 613, 652. The processor serves to perform various operations, for example, in accordance with instructions or programming executable by the processor. Although the processor may be configured by use of hardwired logic, typical processors are general processing circuits configured by execution of programming. The processor can include elements structured and arranged to perform one or more processing functions, typically various data processing functions. Although discrete logic components could be used, the examples utilize components forming a programmable CPU. The processor for example includes one or more integrated circuit (IC) chips incorporating the electronic elements to perform the functions of the CPU. The processor, for example, may be based on any known or available microprocessor architecture, such as a Reduced Instruction Set Computing (RISC) using an ARM architecture, as commonly used today in mobile devices and other portable electronic devices. Of course, other processor circuitry may be used to form the CPU or processor hardware. Although the described examples of the processor each focus on only one microprocessor, for convenience, a multi-processor architecture can also be used. A digital signal processor (DSP) or field-programmable gate array (FPGA) could be suitable replacements for the processor but may consume more power with added complexity. The processor may also partially or fully comprise (1) a single board computer used for local computation, processing, and control of the battery energy storage system 100, energy storage nodes 110A, power conversion system 104, and various controllers; (2) an application-specific integrated circuit used for local computation, processing, and control of the battery energy storage system 100, energy storage nodes 110A, power conversion system 104, and various controllers; (3) other known distributed control system elements; or (4) a combination thereof.

A memory such as 613, 653 can be coupled to the processor 612, 652. Memory devices are for storing data and programming. In the example, memory devices may include a flash memory (non-volatile or persistent storage) and/or a random-access memory (RAM) (volatile storage). The RAM serves as short term storage for instructions and data being handled by the processor e.g., as a working data processing memory. The flash memory typically provides longer term storage.

Of course, other storage devices or configurations may be added to or substituted for those in the example. Such other storage devices may be implemented using any type of storage medium having computer or processor readable instructions or programming stored therein and may include, for example, any or all of the tangible memory of the computers, processors or the like, or associated modules.

A network interface can be coupled to the processor. The network interfaces of the battery energy storage system 100, energy storage nodes 110A, power conversion system 104, and various controllers are configured to communicate with one another.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second, or evident and alternative, and the like may be used solely to distinguish one entity or action from another without necessarily requiring or implying any actual such relationship or order between such entities or actions. The terms “comprises,” “comprising,” “includes,” “including,” or any other variation thereof, are intended to cover a non-exclusive inclusion, such that a process, method, article, or apparatus that comprises or includes a list of elements or steps does not include only those elements or steps but may include other elements or steps not expressly listed or inherent to such process, method, article, or apparatus. An element preceded by “a” or “an” does not, without further constraints, preclude the existence of additional identical elements in the process, method, article, or apparatus that comprises the element.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus, the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present concepts.

What is claimed:

1. An energy storage system, comprising:
a plurality of energy storage nodes arranged in an array, wherein the plurality of energy storage nodes include a plurality of battery modules; and
a control system comprising at least one processor coupled to the plurality of energy storage nodes and a memory configured to receive or store data and programming, wherein the at least one processor is configured to:
perform operations in accordance with execution of the programming;
obtain an initial battery capacity (Cᵢ) for at least one battery module of the plurality of battery modules;
obtain an initial state of charge (SoC₀) of the at least one battery module of the plurality of battery modules;
control at least one sensor to measure and record electrical current flow between multiple components to provide raw data for electrical current within the energy storage system for a predetermined period of time;
determine a present state of charge (SoC₁) of the at least one battery module over an elapsed time of the predetermined period;
determine an integrated current value based upon the measured raw data for the electrical current over the elapsed time for the predetermined period of time;
determine a remaining capacity of the at least one battery module at an end of the elapsed time; and
determine an estimated state of health (SOH) of the at least one battery module based upon the initial battery capacity and the determined remaining capacity including the integrated current value.

2. The energy storage system of claim 1, further comprising a power conversion system (PCS) connected to the plurality of energy storage nodes and an external grid system including an energy source and a connected load, wherein the power conversion system is configured to standardize power inputs and output to and from the plurality of energy storage nodes.

3. The energy storage system of claim 2, wherein the PCS comprises at least one inverter configured to convert bi-directionally between direct current (DC) power and alternating current (AC) power.

4. The energy storage system of claim 2, wherein the PCS comprises at least one direct-current (DC) to direct-current (DC) converter configured to convert a DC source from the plurality of energy storage nodes to a different DC source characteristic.

5. The energy storage system of claim 1, wherein the at least one sensor is further controlled to measure and store operational and environmental data in a memory accessible to the at least one processor of the control system.

6. The energy storage system of claim 1, wherein the remaining capacity of the at least one battery module is: Cᵣ=∫c/(SoC₁−SoC₀),
where: ∫c is the determined integrated current value, SoC₁ is the present state of charge at the predetermined period of time, and SoC₀ is the initial state of charge.

7. The energy storage system of claim 1, wherein the estimated state of health (SoH) is the remaining capacity (Cᵣ) divided by the initial battery capacity (Cᵢ).

8. The energy storage system of claim 1, wherein at least one of maintenance, a repair or a replacement schedule for the at least one battery module is adjusted based on the estimated state of health (SoH).

9. A method, comprising:
obtaining an initial battery capacity (Cᵢ) for at least one battery module of a plurality of battery modules of an energy storage system;
obtaining an initial state of charge (SoC₀) for the at least one battery module of the plurality of battery modules;
controlling at least one sensor to measure and record electrical current flow between multiple components of the energy storage system to provide raw data for electrical current within the energy storage system for a predetermined period of time;
determining a present state of charge (SoC₁) of the at least one battery module over an elapsed time of the predetermined period of time;
determining an integrated current value based upon the measured raw data for the electrical current over the elapsed time for the predetermined period of time;
determining a remaining capacity of the at least one battery module at an end of the elapsed time; and
determining an estimated state of health (SOH) of the at least one battery module based upon the initial battery capacity and the determined remaining capacity including the integrated current value.

10. The method of claim 9, further comprising controlling a power conversion system (PCS) of the energy storage system to standardize power inputs and outputs to and from a plurality of energy storage nodes including the plurality of battery modules, wherein the power conversion system is connected to the plurality of energy storage nodes and an external grid system including an energy source and a connected load.

11. The method of claim 9, further comprising controlling the at least one sensor to measure and store operational data in a memory accessible to the at least one processor of the energy storage system.

12. The method of claim 9, wherein in the determining the remaining capacity, the remaining capacity of the at least one battery module is: Cᵣ=∫c/(SoC₁−SoC₀),
where: ∫c is the determined integrated current value, SoC₁ is the present state of charge at the predetermined period of time, and SoC₀ is the initial state of charge.

13. The method of claim 9, wherein in the determining the estimated state of health (SoH) of the at least one battery module, the estimated SoH is the remaining capacity (Cᵣ) divided by the initial battery capacity (Cᵢ).

14. The method of claim 9, further comprising adjusting at least one of maintenance, a repair or a replacement schedule for the at least one battery module in accordance with the estimated state of health (SoH).

15. A non-transitory computer-readable medium, comprising an estimated state of health (SoH) module, wherein execution of the SoH module by one or more processors configures one or more computing devices to:
obtain an initial battery capacity (Cᵢ) for at least one battery module of a plurality of battery modules of an energy storage system;
obtain an initial state of charge (SoC₀) of the at least one battery module of a plurality of battery modules of the energy storage system;
control at least one sensor to measure and record electrical current flow between multiple components of the energy storage system to provide raw data for electrical current within the energy storage system for a predetermined period of time;
determine a state of charge (SoC₁) of the at least one battery module over an elapsed time of the predetermined period of time;
determine an integrated current value based upon the measured raw data for the electrical current over the elapsed time for the predetermined period of time;
determine a remaining capacity of the at least one battery module at an end of the elapsed time; and
determine an estimated state of health (SOH) of the at least one battery module based upon the initial battery capacity and the determined remaining capacity including the integrated current value.

16. The non-transitory computer-readable medium of claim 15, wherein the one or more computing devices are further configured to control a power conversion system (PCS) of the energy storage system to standardize power inputs and outputs to and from a plurality of energy storage nodes including the plurality of battery modules, wherein the power conversion system is connected to the plurality of energy storage nodes and an external grid system including an energy source and a connected load.

17. The non-transitory computer-readable medium of claim 15, wherein the one or more computing devices are further configured to control the at least one sensor to measure and store operational data in a memory accessible to the at least one processor of the energy storage system.

18. The non-transitory computer-readable medium of claim 15, wherein in the determination of the remaining capacity, the remaining capacity of the at least one battery module is:
$${C}_{r} = \int c / ( {SoC}_{1} - {SoC}_{0} ) ,$$
where: ∫c is the determined integrated current value, SoC₁ is the present state of charge at the predetermined period of time, and SoC₀ is the initial state of charge.

19. The non-transitory computer-readable medium of claim 15, wherein the estimated state of health (SoH) is the remaining capacity (Cᵣ) divided by the initial battery capacity (Cᵢ).

20. The non-transitory computer-readable medium of claim 15, wherein at least one of maintenance, a repair or a replacement schedule for the at least one battery module is adjusted based on the estimated state of health (SoH).
